(19) United States
(12) Patent Application Publication
(10) Pub. No.: US 2004/0239376 A1
(43) Pub. Date: Dec. 2, 2004

(54) Continuously retraining sampler and method of use thereof

(76) Inventor: Jeffrey John Haeffele, Monument, CO (US)

Correspondence Address: AGILENT TECHNOLOGIES, INC., Legal Department, DL429, Intellectual Property Administration, P.O. Box 7599, Loveland, CO, 80537-0599, US

(21) Appl. No.: 10/449,543

(22) Filed: May 30, 2003

(51) Int. Cl. H03K 5/00

(52) U.S. Cl. 327/94

(57) ABSTRACT

A sampling circuit that continuously compensates for drift. The sampling circuit includes a primary sampler surrounded by two proximity samplers. The proximity samplers are used to detect data transitions that encroach on the primary sampler. By comparing the output of the proximity samplers with the primary sampler a determination can be made as to whether data transitions are encroaching on the primary sampler. If such encroachments are detected, the delay timing of the sampling operation may be increased or shortened to compensate.

### BACKGROUND OF THE INVENTION

As digital systems become faster and more complex, test and measurement systems that monitor performance and diagnose problems must also become faster and more complex. A fundamental task of test and measurement system is the extraction of data, termed “samples,” from streams of digital signals. To provide a clear picture of the performance and problems in the digital system, such samples must be error free.

Data sampling circuits must take into account manufacturing process variations, dynamic changes due to drift, power supply fluctuations, clock jitter, and random noise to name of few signal degraders. The classic approach to data sampling has been to increase setup and hold margins until such signal degradations are compensated. This decreases the maximum operating frequency of the test and measurement system. Of these factors, drift, a slow non-random change in a signal over time, has proven to be difficult to eliminate during sampling operations.

Some newer bus protocols, such as PCI-EXPRESS and INFINIBAND embed retraining sequences that allow receiving circuit to adjust their sampling position to account for manufacturing variations and runtime drift. The retraining is activated by a retraining command sent over the bus, reducing bandwidth on the bus. Also, any drift that occurs between training sequences goes uncorrected.

It is known to combine a data signal with an associated clock signal to permit, among other things, continuous correction of drift errors. This approach requires costly circuitry (in terms of both dollars and space) on the transmit and receive ends to combine and separate the signals. For example, phase locked loops are generally added to receive circuits to recover the clock stream. In addition to the extra circuits, the bandwidth for data is reduced by the amount occupied by the clock signal.

Accordingly, the present inventors have recognized a need for new apparatus and methods that continuously track and correct the sampling position for drift that does not require embedded information or limit available bandwidth.

### BRIEF DESCRIPTION OF THE DRAWINGS

An understanding of the present invention can be gained from the following detailed description of the invention, taken in conjunction with the accompanying drawings of which:

FIG. 1 is a block diagram of a sampling circuit in accordance with a preferred embodiment of the present invention.

FIG. 2 is a chart showing signals within the sampling circuit in accordance with a preferred embodiment of the present invention.

### DETAILED DESCRIPTION

Reference will now be made in detail to the present invention, examples of which are illustrated in the accompanying drawings, wherein like reference numerals refer to like elements throughout.

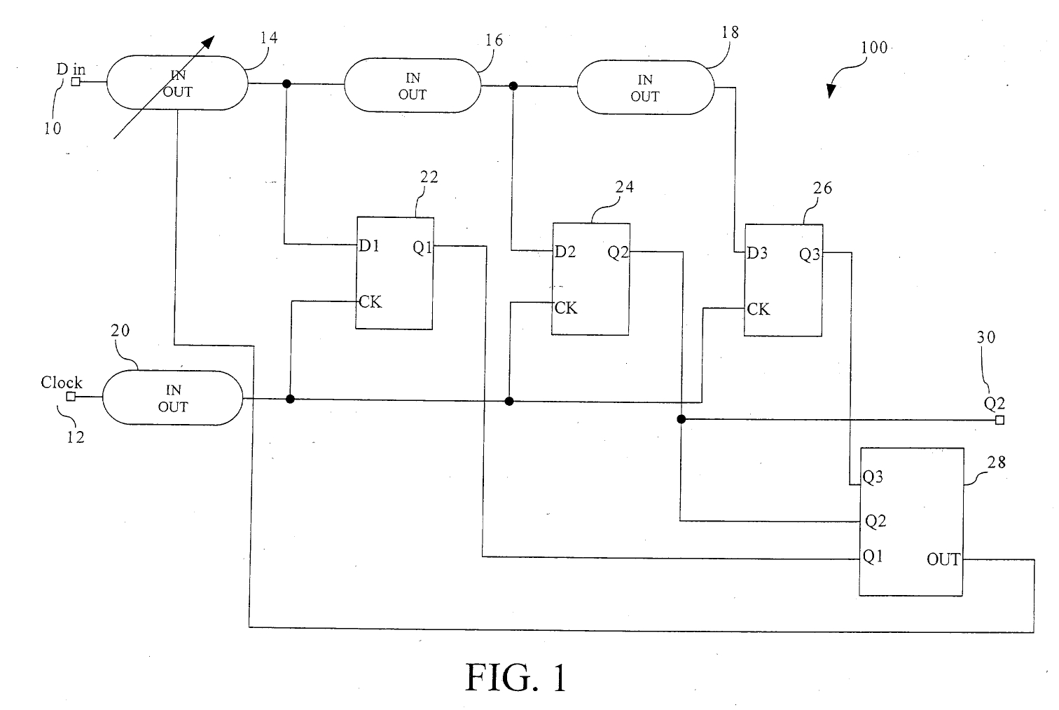

FIG. 1 is a block diagram of a sampling circuit 100 in accordance with a preferred embodiment of the present invention. In general, the sampling circuit 100 receives a data signal 10 and a clock signal 12 and outputs a sample signal 30. The data signal is passed though a series of delay circuits 14, 16, and 18. A further delay circuit 20 delays the clock signal 12. The delay circuits 14 through 20 may be either digital or analog. The output of the delay circuits 14, 16, and 18 are sampled by sample and hold circuits 22, 24 and 26, respectively. The sample and hold circuits are responsive to the delayed clock signal. In FIG. 1, the sample and hold circuits 22-26 are configured as flip-flops, but any circuit capable of sampling and holding the output of the delay circuits 14-18 may be used. The output of each of the sample and hold circuits 14, 16 and 18 is processed by a controller 28 which adjusts the delay of the delay circuit 14 based on the values output by the sample and hold circuits 22-26. The output of the sample and hold circuit 24 is provided as the nominal value of the data signal, e.g. the sample provided by the sampling circuit 100.

The basic concept of the present invention is to surround a primary sampler, i.e. the sample and hold circuit 24, with two proximity samplers, i.e. the sample and hold circuits 22 and 26. The proximity samplers are used to detect data transitions that encroach on the primary sampler. The delay of the delay circuit 14 is increased or decreased if the controller 28 detects such encroachment.

The width of the proximity detect window is set by the delay circuits 16 and 18 and is nominally set to ignore any high frequency jitter of the data signal relative to the clock signal. The delay of circuit 20 is preferably set to the nominal delay value of circuit 14 (generally the center of the range of the available delay) plus the delay of circuit 16. An offset can be further added to the delay of circuit 14 if necessary to match the transmitted timing. The delay circuits 16 and 18 can also be implemented as variable delay circuits, as with the delay circuit 14, to provide control of the proximity window width to allow for application specific amounts of jitter.

The controller 28 can be implemented as either an analog or digital control, depending on the nature of the variable delay circuit 14. Basically, the controller 28 compares the states of the sample and hold circuits 14 through 18 and provides a control signal based on the result of the comparison. Table 1 is one example of a state table that the controller 28 can utilize in formulating the control signal.

TABLE 1

| Q1 | Q2 | Q3 | Delay |
|---|---|---|---|
| 0 | 0 | 0 | Same |
| 0 | 0 | 1 | Decrease |
| 0 | 1 | 0 | Same |
| 0 | 1 | 1 | Increase |
| 1 | 0 | 0 | Increase |
| 1 | 0 | 1 | Same |
| 1 | 1 | 0 | Decrease |
| 1 | 1 | 1 | Same |

The controller 28 is preferably programmed to delay further comparisons and delay adjustments by an amount of time it takes the adjustment to propagate through the sampling circuit 100. It is to be understood that the delay circuit 14 must be capable of providing enough delay to handle any expected variations in input timing that the sampling circuit 100 is tracking. This may be best estimated through experimentation including simulation. It is anticipated that the delay would be on the order of several nonoseconds. Further, the controller 28 can be provided with an exception routine to, for example, reset the delay of the delay circuit 14 to a nominal value or provide an alarm if the encountered drift is outside the operating parameters of the delay circuit 14.

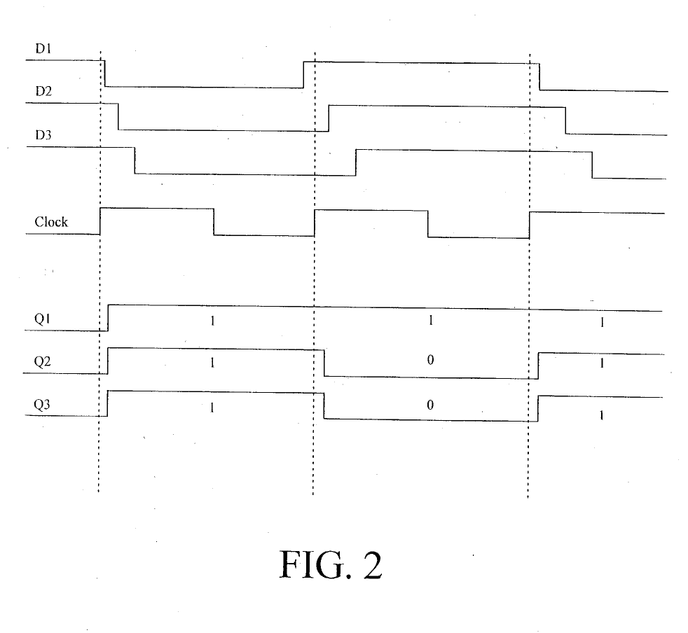

FIG. 2 is a chart showing signals within the sampling circuit 100 in accordance with a preferred embodiment of the present invention. At sample 1, Q1, Q2, and Q3 each have a value of 1, requiring no change in the delay of delay circuit 14. At sample 2, Q1 has a value of “1” while Q2 and Q3 have values of “0,” representing a negative drift. Subsequently, the controller 28 increases the delay of the delay circuit 14 to position the primary sample point, e.g. the sample and hold circuit 16 away from the detected transition region. Thereafter, at sample 3, Q1, Q2 and Q3 each have a value of 1, indicating that the negative drift has been compensated.

Although an embodiment of the present invention has been shown and described, it will be appreciated by those skilled in the art that changes may be made in these embodiments without departing from the principles and spirit of the invention, the scope of which is defined in the claims and their equivalents.

What is claimed is:

1. A sampling circuit comprising:
a variable delay circuit that receives a data signal and delays the output thereof based on a control signal;
a first hold circuit that samples the output of the variable delay circuit based on a clock signal;
a delay circuit that receives the output of the variable delay circuit and delays the output thereof further;
a second hold circuit that samples the output of the delay circuit based on the clock signal;
a second delay circuit that receives the output of the delay circuit and delays the output thereof further;
a third hold circuit that samples the output of the second delay circuit based on the clock signal; and
a control circuit that compares the output of the first, second and third hold circuits and outputs the control signal to adjust the delay of the variable delay circuit to account for drift in the data signal.

2. The sampling circuit, as set forth in claim 1, wherein the delay of the delay circuit is set to correspond to a size of a proximity detect window.

3. The sampling circuit, as set forth in claim 1, wherein the delay of the second delay circuit is set to correspond to a size of a proximity detect window.

4. The sampling circuit, as set forth in claim 1, further comprising a third delay circuit that delays the clock supplied to the first, second and third hold circuits.

5. The sampling circuit, as set forth in claim 4, wherein the delay of the third delay circuit is set to the sum of the nominal delay of the variable delay circuit plus the delay of the delay circuit.

6. The sampling circuit, as set forth in claim 4, wherein the delay of the third delay circuit is set to the sum of the nominal delay of the variable delay circuit plus the delay of the delay circuit and an offset.

7. The sampling circuit, as set forth in claim 1, wherein the delay circuit is a variable delay circuit.

8. The sampling circuit, as set forth in claim 1, wherein the second delay circuit is a variable delay circuit.

9. The sampling circuit, as set forth in claim 4, wherein the third delay circuit is a variable delay circuit.

10. The sampling circuit, as set forth in claim 4, wherein the delay circuit, the second delay circuit and the third delay circuit are each a variable delay circuit.

11. The sampling circuit, as set forth in claim 1, wherein the control circuit is implemented as a state machine.

12. The sampling circuit, as set forth in claim 11, wherein the state machine adjust the delay of the variable delay circuit based on table 1:
TABLE 1

| Q1 | Q2 | Q3 | Delay |
|---|---|---|---|
| 0 | 0 | 0 | Same |
| 0 | 0 | 1 | Decrease |
| 0 | 1 | 0 | Same |
| 0 | 1 | 1 | Increase |
| 1 | 0 | 0 | Increase |
| 1 | 0 | 1 | Same |
| 1 | 1 | 0 | Decrease |
| 1 | 1 | 1 | Same |

wherein Q1 is the output of the first hold circuit, Q2 is the output of the second hold circuit, and Q3 is the output of the third hold circuit.

13. The sampling circuit, as set forth in claim 1 wherein the delay of the variable delay circuit is 10 nanoseconds or less.

14. A method of correction for drift, the method comprising:
receiving a data signal;
passing the data signal through a series of three delay circuits
receiving a clock signal;
sampling the output of each of the three delay circuits based on the clock signal;
comparing the samples and adjusting the delay of the first delay signal to correct for drift.

15. The method of claim 14, further comprising:
delaying the clock signal based on the delay of the first two delay circuits.

16. The method of claim 14, wherein the step of comparing the samples uses table 1 to determine how to adjust the delay of the first delay circuit
TABLE 1

| Q1 | Q2 | Q3 | Delay |
|---|---|---|---|
| 0 | 0 | 0 | Same |
| 0 | 0 | 1 | Decrease |
| 0 | 1 | 0 | Same |
| 0 | 1 | 1 | Increase |
| 1 | 0 | 0 | Increase |
| 1 | 0 | 1 | Same |
| 1 | 1 | 0 | Decrease |
| 1 | 1 | 1 | Same |

wherein Q1 is the sample from the first delay circuit, Q2 is the sample from the delay circuit, and Q3 is the sample from the third delay circuit.

17. A sampling circuit that compensates for drift in a signal, the sampling circuit comprising:
a primary sampler surrounded by first and second proximity samplers that receive the signal at different timing than the primary sampler; and
a control curcuit that compares the output of the proximity samplers with the primary sampler to determine whether data transitions are encroaching on the primary sampler and if such encroachments are detected adjusts a delay timing of the sampling circuit to compensate.
